(19) United States
(12) Patent Application Publication
(10) Pub. No.: US 2023/0006135 A1
(43) Pub. Date: Jan. 5, 2023

(54) COMPOSITION FOR ENCAPSULATING ORGANIC LIGHT EMITTING DIODE AND ORGANIC LIGHT EMITTING DIODE DISPLAY COMPRISING ORGANIC LAYER FORMED USING THE SAME

(71) Applicant: SAMSUNG SDI CO., LTD., Yongin-si (KR)

(72) Inventors: Seong Ryong NAM, Suwon-si (KR); Myong Sook HAN, Suwon-si (KR); Ji Yeon LEE, Suwon-si (KR); Chang Won PARK, Suwon-si (KR); Jee Hyun RYU, Suwon-si (KR)

(21) Appl. No.: 17/838,548

(22) Filed: Jun. 13, 2022

(30) Foreign Application Priority Data
Jun. 17, 2021 (KR) 10-2021-0078432

(51) Int. Cl. H01L 51/00; C09D 151/08

(52) U.S. Cl. CPC H01L 51/004; C09D 151/085; H01L 51/5253

(57) ABSTRACT

A composition for encapsulation of organic light emitting diodes and an organic light emitting diode display apparatus, the composition including photocurable monomers and having a CLD of 50 or more, as calculated by Equation 1:

$$CLD = \sum \frac{{M}_{x} ( {N}_{x} - 1 )}{{M}_{total}} \qquad [ Equation 1 ]$$

wherein, in Equation 1, Mₜₒₜₐₗ is a total sum of a number of moles of the photocurable monomers in the composition, Mₓ is a number of moles of an x^{th} photocurable monomer in the composition, Nₓ is a number of photocurable functional groups per mole of the x^{th} photocurable monomer in the composition, and x is an integer of 1 or more.

### CROSS-REFERENCE TO RELATED APPLICATION

This application claims the benefit of Korean Patent Application No. 10-2021-0078432, filed on Jun. 17, 2021, in the Korean Intellectual Property Office, the entire disclosure of which is incorporated herein by reference.

### BACKGROUND

### 1. Field

Embodiments relate to a composition for encapsulation of organic light emitting diodes and an organic light emitting diode display including an organic layer formed using the same.

### 2. Description of the Related Art

An organic light emitting diode may suffer from deterioration in reliability upon contact with external moisture or oxygen. Thus, the organic light emitting diode may be encapsulated with an encapsulation layer including an organic layer formed of a composition for encapsulation of organic light emitting diodes and an inorganic layer.

The encapsulation layer may have a structure in which organic layers and inorganic layers are repeatedly stacked one above another. The encapsulation layer may be formed on the organic light emitting diode by alternately forming the organic layers and the inorganic layers in the sequence of, e.g., organic layer-inorganic layer-organic layer-inorganic layer. The inorganic layers may be formed of inorganic materials unlike the organic layers. In general, the inorganic layers may be formed by a plasma process and a vacuum process, e.g., sputtering, chemical vapor deposition, plasma chemical vapor deposition, evaporation, sublimation, electron cyclotron resonance-plasma vapor deposition, or a combination thereof.

### SUMMARY

The embodiments may be realized by providing a composition for encapsulation of organic light emitting diodes, the composition comprising photocurable monomers and having a CLD of 50 or more, as calculated by Equation 1:

$$CLD = \sum \frac{{M}_{x} ( {N}_{x} - 1 )}{{M}_{total}} \qquad [ Equation 1 ]$$

wherein, in Equation 1, Mₜₒₜₐₗ is a total sum of a number of moles of the photocurable monomers in the composition, Mₓ is a number of moles of an x^{th} photocurable monomer in the composition, N_{X} is a number of photocurable functional groups per mole of the x^{th} photocurable monomer in the composition, and x is an integer of 1 or more.

The composition may have a CLD of 50 to 90.

The composition may include a first photocurable monomer; a second photocurable monomer; and an initiator, the first photocurable monomer may have at least two photocurable functional groups, and the second photocurable monomer may have a single photocurable functional group.

The first photocurable monomer may be present in an amount of 35 parts by weight to 90 parts by weight, the second photocurable monomer may be present in an amount of 5 parts by weight to 60 parts by weight, and the initiator may be present in an amount of 1 part by weight to 10 parts by weight, all based on 100 parts by weight of total of the first photocurable monomer, the second photocurable monomer, and the initiator.

The first photocurable monomer may include a bifunctional (meth)acrylate represented by Formula 1, trimethylolpropane tri(meth)acrylate, pentaerythritol tri(meth)acrylate, dipentaerythritol tri(meth)acrylate, tris(2-hydroxyethyl)isocyanurate tri(meth)acrylate, pentaerythritol tetra(meth)acrylate, dipentaerythritol tetra(meth)acrylate, ditrimethylolpropane tetra(meth)acrylate, dipentaerythritol penta(meth)acrylate, or dipentaerythritol hexa(meth)acrylate,

Z₁—A₁—A—A₂—Z₂ [Formula 1]

in Formula 1, A may be a substituted or unsubstituted C₆ to C₂₀ alkylene group or a substituted or unsubstituted C₃ to C₂₀ cycloalkylene group; A₁ and A₂ may be each independently a single bond or a substituted or unsubstituted C₁ to C₁₀ alkylene group, and Z₁ and Z₂ may be each independently a group represented by Formula 2,

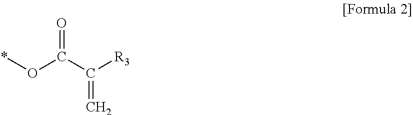

in Formula 2, * is a linking site to A₁ or A₂, and R₃ may be hydrogen or a methyl group.

The first photocurable monomer may include a photocurable monomer represented by Formula 3:

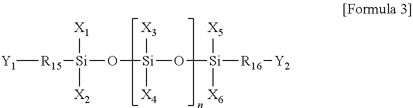

in Formula 3, R₁₅ and R₁₆ may be each independently a single bond, a substituted or unsubstituted C₁ to C₂₀ alkylene group, a substituted or unsubstituted C₁ to C₃₀ alkylene ether group, *—N(R′)—R″—*, in which * is a linkage site, R′ is a substituted or unsubstituted C₁ to C₃₀ alkyl group, and R″ is a substituted or unsubstituted C₁ to C₂₀ alkylene group, a substituted or unsubstituted C₆ to C₃₀ arylene group, a substituted or unsubstituted C₇ to C₃₀ arylalkylene group, or *—O—G″—*, in which * is a linkage site and G″ is a substituted or unsubstituted C₁ to C₂₀ alkylene group; X₁, X₂, X₃, X₄, X₅, and X₆ may be each independently hydrogen, a substituted or unsubstituted C₁ to C₃₀ alkyl group, a substituted or unsubstituted C₁ to C₃₀ alkyl ether group, *—N(E′)(E″), in which * is a linkage site and E′ and E″ are each independently a hydrogen or a substituted or unsubstituted C₁ to C₃₀ alkyl group, a substituted or unsubstituted C₁ to C₃₀ alkyl sulfide group, a substituted or unsubstituted C₆ to C₃₀ aryl group, or a substituted or unsubstituted C₇ to C₃₀ arylalkyl group; n may range from 0 to 30 on average; and Y₁ and Y₂ may be each independently represented by Formula 4,

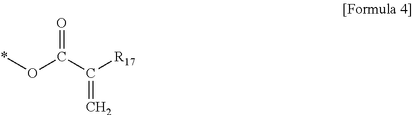

in Formula 4, * is a linkage site to R₁₅ or R₁₆, and R₁₇ may be hydrogen or a methyl group.

The second photocurable monomer may include an aromatic photocurable monomer or a non-aromatic photocurable monomer.

The composition may have a viscosity of 7 cP to 100 cP at 25±2° C.

The embodiments may be realized by providing an organic light emitting diode display apparatus including an organic layer prepared from the composition for encapsulation of organic light emitting diodes according to an embodiment.

### BRIEF DESCRIPTION OF THE DRAWINGS

Features will be apparent to those of skill in the art by describing in detail exemplary embodiments with reference to the attached drawings in which:

FIG. 1 is a sectional view of an organic light emitting diode display according to one embodiment.

FIG. 2 is a sectional view of an organic light emitting diode display according to another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. Like reference numerals refer to like elements throughout.

In the drawings, portions irrelevant to the description may be omitted for clarity.

As used herein, the term “(meth)acryl” may refer to “acryl” or “methacryl”. As used herein, the term “or” is not an exclusive term, e.g., “A or B” would include A, B, or A and B.

As used herein, unless otherwise stated, the term “substituted” means that at least one hydrogen atom of a functional group is substituted with a halogen (for example, F, Cl, Br or I), a hydroxyl group, a nitro group, a cyano group, an imino group (═NH, ═NR, R being a C₁ to C₁₀ alkyl group), an amino group (—NH₂, —NH(R′), —N(R″)(R′″), R′, R″ and R′″ being each independently a C₁ to C₁₀ alkyl group), an amidino group, a hydrazine or hydrazone group, a carboxyl group, a C₁ to C₂₀ alkyl group, a C₆ to C₃₀ aryl group, a C₃ to C₃₀ cycloalkyl group, a C₃ to C₃₀ heteroaryl group, or a C₂ to C₃₀ heterocycloalkyl group.

As used herein to represent a specific numerical range, the expression “X to Y” means “greater than or equal to X and less than or equal to Y (X≤ and ≤Y)”.

A composition for encapsulation of organic light emitting diodes (hereinafter referred to as a “composition”) according to an embodiment may form an organic layer having high hardness. As described in greater detail below, an inorganic layer may be deposited on an organic layer to act as an encapsulation layer for an organic light emitting diode. The encapsulation layer may be formed by repeatedly and alternately stacking organic layers and inorganic layers and serves to encapsulate the organic light emitting diode. The inorganic layers may be formed by, e.g., chemical vapor deposition (CVD). The embodiments may provide a composition for encapsulation of organic light emitting diodes, which may form an organic layer having high hardness and good reliability while suppressing generation of wrinkles in the organic layer upon repeated formation of the inorganic layers through CVD. In addition, the composition according to an embodiment may have suitable viscosity for an ink-jet process to help secure good ink-jet properties, thereby providing an organic layer having a uniform surface.

According to one embodiment, the composition for encapsulation of organic light emitting diodes (hereinafter referred to as “composition”) may have a CLD (Cross Linking Density) of, e.g., 50 or more, as calculated by Equation 1:

$$CLD = \sum \frac{{M}_{x} ( {N}_{x} - 1 )}{{M}_{total}} \qquad [ Equation 1 ]$$

In Equation 1, Mₜₒₜₐₗ is a total sum of a number of moles of photocurable monomers in the composition,

Mₓ is a number of moles of an x^{th} photocurable monomer in the composition,

Nₓ is a number of photocurable functional groups per mole of the x^{th} photocurable monomer in the composition, and

x is an integer of 1 or more.

In an implementation, x may be, e.g., an integer of 2 or more, or an integer of 2 to 5, or 2, 3, 4, 5. The photocurable functional group may be an acrylate group or a methacrylate group. Nₓ may be, e.g., an integer of 1 or more, or an integer of 1 to 6, or 1, 2, 3, 4, 5, 6.

CLD is a criterion for determining whether advantageous effects of the embodiments may be realized by securing high hardness by allowing the photocurable monomers in the composition to be cured at high crosslinking density when the photocurable monomers are cured through irradiation with light. CLD is a criterion for determining whether photocurable monomers having two or more photocurable functional groups can increase the crosslinking density through double or more crosslinking when cured through irradiation with light. CLD is different from the photocuring rate of the composition. The photocuring rate indicates a cured ratio of the photocurable monomers in the composition, whereas CLD determines whether the photocurable monomers having two or more functional groups among the photocurable monomers can be cured at high crosslinking density to increase hardness.

In an implementation, the composition may have a CLD of, e.g., 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, or 90. In an implementation, the composition may have a CLD of 50 to 90, 50 to 80, or 50 to 70.

In an implementation, an organic layer formed of the composition may have a hardness of 200 kPa or more, e.g., 200 kPa, 205 kPa, 210 kPa, 215 kPa, 220 kPa, 225 kPa, 230 kPa, 235 kPa, 240 kPa, 245 kPa, 250 kPa, 255 kPa, 260 kPa, 265 kPa, 270 kPa, 275 kPa, 280 kPa, 285 kPa, 290 kPa, 295 kPa, 300 kPa, or 200 kPa to 300 kPa. Within this range, the composition may easily realize the advantageous effects of the embodiments.

The composition may be a suitable composition that can achieve a CLD of 50 or more, as calculated by Equation 1. In an implementation, the composition may include, e.g., a first photocurable monomer, a second photocurable monomer, and an initiator.

A weight ratio of the first photocurable monomer to the second photocurable monomer in the composition may be in the range of 0.5 to 6, e.g., 0.5, 1, 1.5, 2, 2.5, 3, 3.5, 4, 4.5, 5, 5.5, 6, or 0.7 to 5.5. Within this range, the composition may easily realize the advantageous effects of the embodiments.

Hereinafter, each component of the composition according to one embodiment will be described.

First Photocurable Monomer

The first photocurable monomer may include a monomer having at least two photocurable functional groups. In an implementation, the first photocurable monomer may have two to six photocurable functional groups.

In an implementation, the first photocurable monomer may include a silicon-free monomer or a silicone photocurable monomer, e.g., containing silicon.

Silicon-Free Photocurable Monomer

In an implementation, the silicon-free photocurable monomer may include, e.g., a bifunctional (meth)acrylate represented by Formula 1.

Z₁—A₁—A—A₂—Z₂ [Formula 1]

In Formula 1, A may be or may include, e.g., a substituted or unsubstituted C₆ to C₂₀ alkylene group or a substituted or unsubstituted C₃ to C₂₀ cycloalkylene group.

A₁ and A₂ may each independently be or include, e.g., a single bond or a substituted or unsubstituted C₁ to C₁₀ alkylene group.

Z₁ and Z₂ may each independently be, e.g., a group represented by Formula 2.

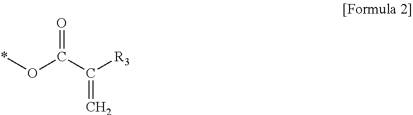

In Formula 2, * is a linking site (e.g., to A₁ or A₂), and R₃ may be, e.g., hydrogen or a methyl group.

In an implementation, A may be, e.g., a substituted or unsubstituted C₃ to C₂₀ cycloalkylene group. In this case, the composition may easily realize the advantageous effects of the embodiments. In an implementation, the compound of Formula 1 may include, e.g., tricyclodecane dimethanol di(meth)acrylate or cyclohexane dimethanol di(meth)acrylate.

In an implementation, the silicon-free photocurable monomer may include, e.g., tri(meth)acrylate, tetra(meth)acrylate, penta(meth)acrylate, or hexa(meth)acrylate as a tri- or higher polyfunctional (meth)acrylate, in addition to the compound of Formula 1. The tri(meth)acrylate may include tri(meth)acrylates of C₃ to C₂₀ triols, tetraols, pentaols or hexaols including trimethylolpropane tri(meth)acrylate, pentaerythritol tri(meth)acrylate, dipentaerythritol tri(meth)acrylate, tris(2-hydroxyethyl)isocyanurate tri(meth)acrylate, or the like. The tetra(meth)acrylate may include tetra(meth)acrylates of C₄ to C₂₀ tetraols, pentaols or hexaols including pentaerythritol tetra(meth)acrylate, dipentaerythritol tetra(meth)acrylate, ditrimethylolpropane tetra(meth)acrylate, or the like. The penta(meth)acrylate may include penta(meth)acrylates of C₄ to C₂₀ pentaols or hexaols including dipentaerythritol penta(meth)acrylate or the like. The hexa(meth)acrylate may include hexa(meth)acrylates of C₄ to C₂₀ hexaol including dipentaerythritol hexa(meth)acrylate or the like.

Silicone Photocurable Monomer

In an implementation, the silicone photocurable monomer may be represented by Formula 3.

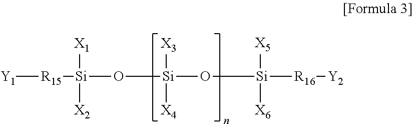

In Formula 3, R₁₅ and R₁₆ may each independently be or include, e.g., a single bond, a substituted or unsubstituted C₁ to C₂₀ alkylene group, a substituted or unsubstituted C₁ to C₃₀ alkylene ether group, *—N(R′)—R″—* (in which * is a linkage site, R′ may be a substituted or unsubstituted C₁ to C₃₀ alkyl group, and R″ may be a substituted or unsubstituted C₁ to C₂₀ alkylene group), a substituted or unsubstituted C₆ to C₃₀ arylene group, a substituted or unsubstituted C₇ to C₃₀ arylalkylene group, or *—O—R″—* (in which * is a linkage site and R″ is a substituted or unsubstituted C₁ to Czo alkylene group).

X₁, X₂, X₃, X₄, X₅, and X₆ may each independently be or include, e.g., hydrogen, a substituted or unsubstituted C₁ to C₃₀ alkyl group, a substituted or unsubstituted C₁ to C₃₀ alkyl ether group, *—N(E′)(E″) (in which * is a linkage site, and E and E′ are each independently hydrogen or a substituted or unsubstituted C₁ to C₃₀ alkyl group), a substituted or unsubstituted C₁ to C₃₀ alkyl sulfide group, a substituted or unsubstituted C₆ to C₃₀ aryl group, or a substituted or unsubstituted C₇ to C₃₀ arylalkyl group.

Y₁ and Y₂ may each independently be, e.g., a group represented by Formula 4.

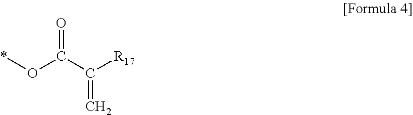

In Formula 4, * is a linkage site to R₁₅ or R₁₆, and R₁₇ may be, e.g., hydrogen or a methyl group.

n may be, e.g., an integer of 0 to 30 or may range from 0 to 30 on average.

Here, “single bond” refers to a direct bond (Y₁—Si) between Si and Y₁ without any intervening element therebetween or a direct bond (Si—Y₂) between Si and Y₂ without any intervening element therebetween.

In an implementation, R₁₅ and R₁₆ may be, e.g., a C₁ to C₅ alkylene group or a single bond.

In an implementation, at least one of X₁, X₂, X₃, X₄, X₅, and X₆ may be, e.g., a substituted or unsubstituted C₆ to C₃₀ aryl group. In an implementation, X₁, X₂, X₃, X₄, X₅, and X₆ may each independently be, e.g., a substituted or unsubstituted C₁ to C₅ alkyl group or a substituted or unsubstituted C₆ to C₁₀ aryl group, in which at least one of X₁, X₂, X₃, X₄, X₅, and X₆ may be a substituted or unsubstituted C₆ to C₁₀ aryl group. In an implementation, X₁, X₂, X₃, X₄, X₅, and X₆ may each independently be, e.g., a substituted or unsubstituted C₁ to C₅ alkyl group or a substituted or unsubstituted C₆ to C₁₀ aryl group, in which one, two, three, or six of X₁, X₂, X₃, X₄, X₅, and X₆ may be a substituted or unsubstituted C₆ to CM aryl group. In an implementation, X₁, X₂, X₃, X₄, X₅, and X₆ may each independently be, e.g., a substituted or unsubstituted methyl group, a substituted or unsubstituted ethyl group, a substituted or unsubstituted propyl group, a substituted or unsubstituted butyl group, a substituted or unsubstituted pentyl group, a substituted or unsubstituted phenyl group, or a substituted or unsubstituted naphthyl group, in which one, two, three, or six of X₁, X₂, X₃, X₄, X₅, and X₆ may be a substituted or unsubstituted phenyl group or a substituted or unsubstituted naphthyl group. n may be, e.g., an integer of 1 to 5.

In an implementation, X₁, X₂, X₃, X₄, X₅, and X₆ may each independently be, e.g., a substituted or unsubstituted C₁ to C₃₀ alkyl group. In an implementation, X₁, X₂, X₃, X₄, X₅, and X₆ may each independently be, e.g., a substituted or unsubstituted C₁ to C₅ alkyl group. In an implementation, X₁, X₂, X₃, X₄, X₅, and X₆ may each independently be, e.g., a substituted or unsubstituted methyl group.

In an implementation, the silicone-based photocurable monomer may be represented by, e.g., one of Formulae 3-1 to 3-7.

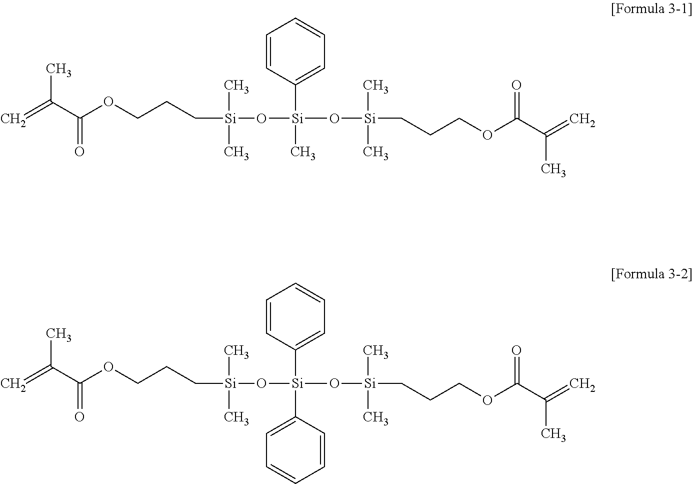

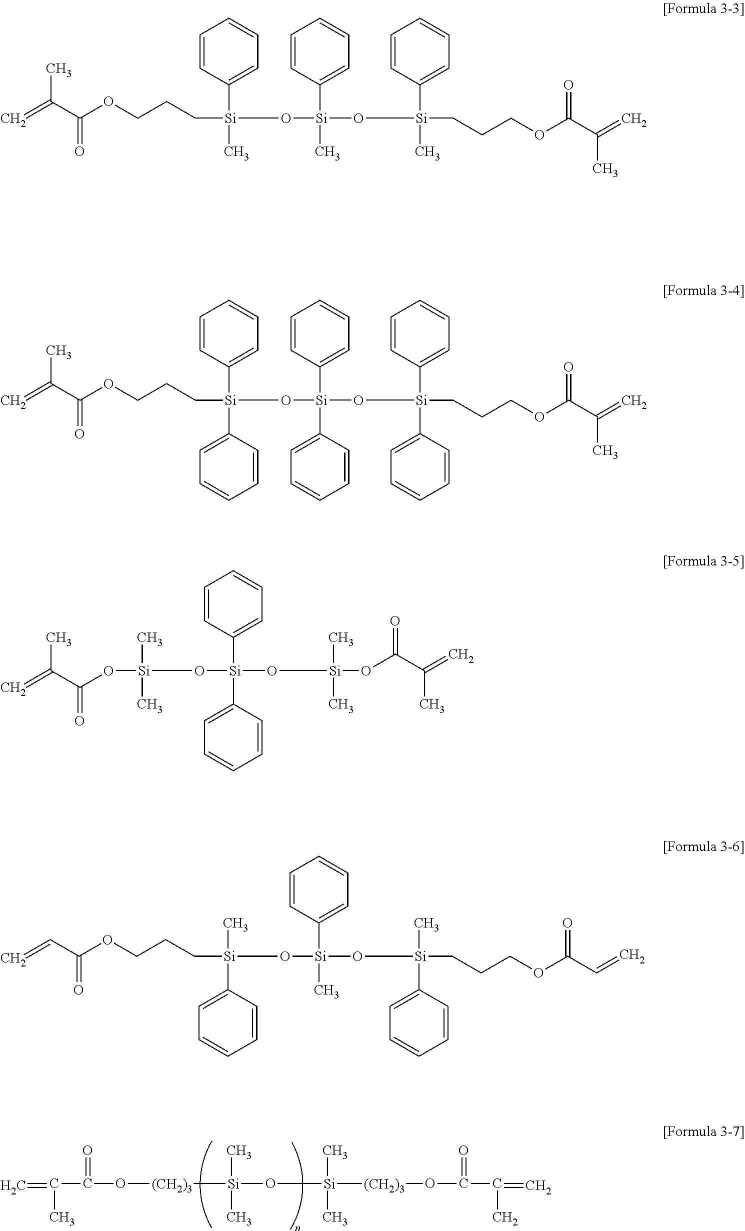

In Formulae 3 to 7, n may be, e.g., an integer of 1 to 31 or may range from 1 to 31 on average.

The monomer of Formula 3 may be prepared by a suitable method or may be obtained from commercially available products. In an implementation, the monomer of Formula 3 may be prepared by, e.g., reacting a siloxane compound having at least one silicon bond and containing an aryl group with a compound for extending the carbon number (e.g., allyl alcohol), followed by reacting with (meth)acryloyl chloride. In an implementation, the monomer of Formula 3 may be prepared by, e.g., reacting a siloxane compound having at least one silicone bond and containing an aryl group with (meth)acryloyl chloride.

In an implementation, the first photocurable monomer may be present in an amount of 35 parts by weight to 90 parts by weight, e.g., 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90 parts by weight, or 40 parts by weight to 85 parts by weight, relative to 100 parts by weight of the first photocurable monomer, the second photocurable monomer, and the initiator. Within this range, the composition may easily achieve a CLD of 50 or more, as calculated by Equation 1.

Second Photocurable Monomer

The second photocurable monomer may include a monomer having one photocurable functional group. The second photocurable monomer may have one photocurable functional group, and the second photocurable monomer may not affect the CLD, e.g., of 50 or more. In an implementation, with the second photocurable monomer, the composition may exhibit suitable viscosity to improve ink-jet properties and may form an organic layer having a uniform surface.

The second photocurable monomer may include an aromatic photocurable monomer containing an aromatic group or a non-aromatic photocurable monomer free from an aromatic group.

Aromatic Photocurable Monomer

The aromatic photocurable monomer may include a compound represented by, e.g., Formula 5.

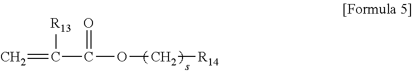

In Formula 5, R₁₃ may be, e.g., hydrogen or a methyl group.

s may be, e.g., an integer of 0 to 10.

R₁₄ may be or may include, e.g., a substituted or unsubstituted C₆ to C₅₀ aryl group or a substituted or unsubstituted C₆ to C₅₀ aryloxy group.

In an implementation, R₁₄ may be a substituted or unsubstituted one of, e.g., a phenylphenoxyethyl group, a phenoxyethyl group, a benzyl group, a phenyl group, a phenylphenoxy group, a phenoxy group, a phenylethyl group, a phenylpropyl group, a phenylbutyl group, a methylphenylethyl group, a propylphenylethyl group, a methoxyphenylethyl group, a cyclohexylphenylethyl group, a chlorophenylethyl group, a bromophenylethyl group, a methylphenyl group, a methylethylphenyl group, a methoxyphenyl group, a propylphenyl group, a cyclohexylphenyl group, a chlorophenyl group, a bromophenyl group, a phenylphenyl group, a biphenyl group, a terphenyl group, a quaterphenyl group, an anthracenyl group, a naphthalenyl group, a triphenylenyl group, a methylphenoxy group, an ethylphenoxy group, a methylethylphenoxy group, a methoxyphenyloxy group, a propylphenoxy group, a cyclohexylphenoxy group, a chlorophenoxy group, a bromophenoxy group, a biphenyloxy group, a terphenyloxy group, a quaterphenyloxy group, an anthracenyloxy group, a naphthalenyloxy group, or a triphenylenyloxy group.

In an implementation, the compound represented by Formula 5 may include, e.g., 2-phenylphenoxyethyl (meth)acrylate, phenoxyethyl (meth)acrylate, phenyl (meth)acrylate, phenoxy (meth)acrylate, 2-ethylphenoxy (meth)acrylate, benzyl (meth)acrylate, 2-phenylethyl (meth)acrylate, 3-phenylpropyl (meth)acrylate, 4-phenylbutyl (meth)acrylate, 2-(2-methylphenyl)ethyl(meth)acrylate, 2-(3-methylphenyl)ethyl(meth)acrylate, 2-(4-methylphenyl)ethyl(meth)acrylate, 2-(4-propylphenyl)ethyl(meth)acrylate, 2-(4-(1-methylethyl)phenyl)ethyl(meth)acrylate, 2-(4-methoxyphenyl)ethyl (meth)acrylate, 2-(4-cyclohexylphenyl)ethyl (meth)acrylate, 2-(2-chlorophenyl)ethyl(meth)acrylate, 2-(3-chlorophenyl)ethyl(meth)acrylate, 2-(4-chlorophenyl)ethyl(meth)acrylate, 2-(4-bromophenyl)ethyl(meth)acrylate, 2-(3-phenylphenyl)ethyl(meth)acrylate, 4-(biphenyl-2-yloxy)butyl(meth)acryl ate, 3-(biphenyl-2-yloxy)butyl(meth)acrylate, 2-(biphenyl-2-yloxy)butyl(meth)acrylate, 1-(biphenyl-2-yloxy)butyl(meth)acrylate, 4-(biphenyl-2-yloxy)propyl(meth)acrylate, 3-(biphenyl-2-yloxy)propyl(meth)acrylate, 2-(biphenyl-2-yloxy)propyl(meth)acrylate, 1-(biphenyl-2-yloxy)propyl(meth)acrylate, 4-(biphenyl-2-yloxy)ethyl(meth)acrylate, 3-(biphenyl-2-yloxy)ethyl(meth)acrylate, 2-(biphenyl-2-yloxy)ethyl(meth)acrylate, 1-(biphenyl-2-yloxy)ethyl(meth)acrylate, 2-(4-benzylphenyl)ethyl(meth)acrylate, 1-(4-benzylphenyl)ethyl(meth)acrylate, or structural isomers thereof In an implementation, although 2-phenylethyl (meth)acrylate is mentioned, the compound may include, e.g., any of 3-phenylethyl (meth)acrylate or 4-phenyl (meth)acrylate.

Non-Aromatic Photocurable Monomer

The non-aromatic mono(meth)acrylate may include a linear or branched C₁ to C₂₀ alkyl group-containing mono(meth)acrylate. In an implementation, the non-aromatic photocurable monomer may include, e.g., octyl (meth)acrylate, nonyl (meth)acrylate, lauryl (meth)acrylate, tetradecyl based (meth)acrylate including tetradecyl (meth)acrylate, 2-decyl tetradecyl (meth)acrylate and the like, undecyl (meth)acrylate, dodecyl (meth)acrylate, or isostearyl (meth)acrylate.

In an implementation, the second photocurable monomer may be present in an amount of 5 parts by weight to 60 parts by weight, e.g., 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60 parts by weight, or 10 parts by weight to 60 parts by weight, relative to 100 parts by weight of the first photocurable monomer, the second photocurable monomer, and the initiator. Within this range, the composition may easily achieve a CLD of 50 or more, as calculated by Equation 1, and may form an organic layer having a uniform surface while improving ink-jet properties.

Initiator

The photoradical initiator may include a suitable photoradical initiator that may initiate a photocuring reaction. In an implementation, the photoradical initiator may include, e.g., a triazine initiator, an acetophenone initiator, a benzophenone initiator, a thioxanthone initiator, a benzoin initiator, a phosphorus initiator, an oxime initiator, or a mixture thereof

In an implementation, the initiator may include a phosphorus initiator having a maximum absorption wavelength of 360 nm to 400 nm. The phosphorus initiator may be advantageously used to initiate photocuring of the composition upon irradiation with long-wavelength UV (e.g., 300 nm to 400 nm). Examples of the phosphorus initiator may include diphenyl(2,4,6-trimethylbenzoyl)phosphine oxide, phenyl bis(2,4,6-trimethylbenzoyl)phosphine oxide, 2,4,6-trimethylbenzoyl diphenyl phosphinate, or a mixture thereof. These initiators may be used alone or in combination thereof. Here, “maximum absorption wavelength” may be measured by a conventional method known to those skilled in the art or obtained by referring to a product catalog.

The initiator may be present in an amount of 1 part by weight to 10 parts by weight, e.g., 1 part by weight to 5 parts by weight, relative to 100 parts by weight of the first photocurable monomer, the second photocurable monomer, and the initiator. Within this range, the composition can be sufficiently cured upon exposure to light while preventing reduction in light transmittance due to remaining initiator.

The composition according to an embodiment may be prepared by mixing the first photocurable monomer, the second photocurable monomer, and the initiator. In an implementation, the composition may be a solvent-free type, e.g., that does not contain any solvent.

The composition according to an embodiment may be a photocurable composition and may be cured to form an encapsulation layer through, e.g., UV irradiation at 10 mW/cm² to 500 mW/cm² for 1 second to 50 seconds.

In an implementation, the composition may further include an additive. Examples of the additives may include a heat stabilizer, an antioxidant, and a UV absorber.

In an implementation, the composition may have a viscosity of, e.g., 7 cP to 100 cP, 7 cP to 60 cP, or 7 cP to 50 cP, at 25±2° C. (23° C. to 28° C.). Within this range, the composition may exhibit good ink-jet properties.

In an implementation, the composition may have a photocuring rate of, e.g., 89% to 100%, 91% to 99%, or 91% to 93%. Within this range, the composition can form an organic layer. The photocuring rate may be calculated by Equation 2 mentioned below.

The composition according to an embodiment may be used to encapsulate an organic light emitting diode. In an implementation, the composition may form organic layers in an encapsulation structure in which organic and inorganic layers are sequentially formed one above another.

The composition according to an embodiment may be used to encapsulate a member for apparatuses, which could otherwise suffer from degradation or faults due to permeation of surrounding gases or liquids, e.g., atmospheric oxygen, moisture, or water vapor and due to permeation of chemicals used in fabrication of electronics. Examples of the member for apparatuses may include luminaires, metal sensor pads, microdisc lasers, electrochromic devices, photochromic devices, microelectromechanical systems, solar cells, integrated circuits, charge coupled devices, and light emitting polymers.

An organic light emitting diode display according to an embodiment may include an organic layer formed of or prepared from the composition according to the embodiments. In an implementation, the organic light emitting diode display may include an organic light emitting diode and a barrier stack formed on the organic light emitting diode and including an inorganic layer and an organic layer, wherein the organic layer may be formed of the composition according to the embodiments. Thus, the organic light emitting display may have high reliability.

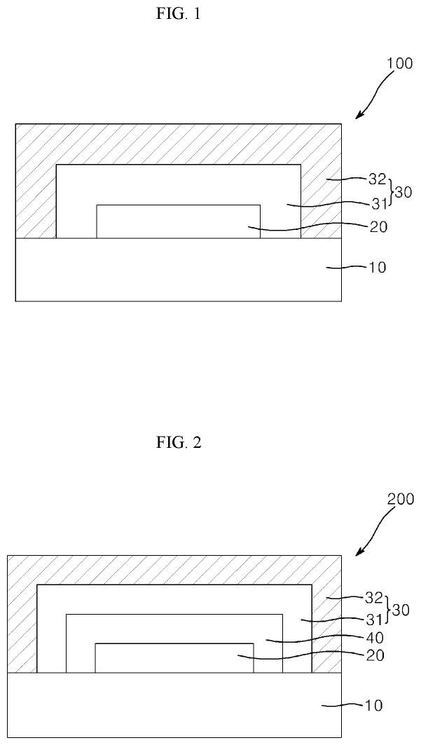

Next, an organic light emitting diode display according to one embodiment will be described with reference to FIG. 1. FIG. 1 is a sectional view of an organic light emitting diode display according to one embodiment.

Referring to FIG. 1, the organic light emitting display 100 according to the embodiment may include a substrate 10, an organic light emitting diode 20 on the substrate 10, and a barrier stack 30 on the organic light emitting diode 20 and including an inorganic layer 31 and an organic layer 32. The inorganic layer 31 may adjoin the organic light emitting diode 20, and the organic layer 32 may be formed of or prepared from the composition for encapsulation of organic light emitting diodes according to the embodiments.

The substrate 10 may be a suitable substrate upon which an organic light emitting diode may be formed. In an implementation, the substrate 10 may include, e.g., a transparent glass substrate, a plastic sheet substrate, a silicon substrate, a metal substrate, or the like.

The organic light emitting diode 20 may include a suitable organic light emitting diode used in organic light emitting diode displays. In an implementation, the organic light emitting diode 20 may include a first electrode, a second electrode, and an organic light emitting layer between the first electrode and the second electrode. In an implementation, the organic light emitting layer may have a structure in which a hole injection layer, a hole transport layer, a light emitting layer, an electron transport layer, and an electron injection layer are sequentially stacked.

The barrier stack 30 may include the organic layer and the inorganic layer, which are formed of different materials, thereby realizing a function of encapsulating the organic light emitting diode.

The inorganic layer may be formed of a different material than the organic layer to supplement effects of the organic layer. In an implementation, the inorganic layer may be formed of a different material than the organic layer to supplement encapsulation provided by the organic layer. In an implementation, the inorganic layer may include, e.g., metals; nonmetals; intermetallic compounds or alloys; non-metallic compounds or alloys; oxides of metals or nonmetals; fluorides of metals or nonmetals; nitrides of metals or nonmetals; carbides of metals or nonmetals; oxynitrides of metals or nonmetals; borides of metals or nonmetals; oxyborides of metals or nonmetals; silicides of metals or nonmetals; or mixtures thereof. The metals or the nonmetals may include, e.g., silicon (Si), aluminum (Al), selenium (Se), zinc (Zn), antimony (Sb), indium (In), germanium (Ge), tin (Sn), bismuth (Bi), transition metals, or lanthanide metals. In an implementation, the inorganic layer may be silicon oxide (SiOₓ), silicon nitride (SiNₓ), silicon oxynitride (SiOₓN_{y}), zinc selenide (ZnSe), zinc oxide (ZnO), antimony trioxide (Sb₂O₃), aluminum oxide (AlOₓ) including alumina (Al₂O₃), indium oxide (In2O3), or tin oxide (SnO₂).

The inorganic layer may be deposited by a plasma process or a vacuum process, e.g., sputtering, chemical vapor deposition, plasma chemical vapor deposition, evaporation, sublimation, electron cyclotron resonance-plasma enhanced chemical vapor deposition, or a combination thereof.

The organic layer may be alternately deposited with the inorganic layer, thereby securing smoothing properties of the inorganic barrier layer while preventing defects of one inorganic layer from spreading to other inorganic layers.

The organic layer may be formed by a combination of coating, deposition, and curing of the composition for encapsulation of organic light emitting diodes according to the embodiments. In an implementation, the organic layer may be formed by coating the composition to a thickness of about 1 μm to about 50 μm, followed by curing the composition through light irradiation at about 10 mW/cm² to about 500 mW/cm² for about 1 second to 50 seconds.

The barrier stack may include a suitable number of the organic layers and inorganic layers. The total number of organic and inorganic layers may vary depending on the desired level of permeation resistance to oxygen and/or moisture or water vapor or chemicals. In an implementation, the organic and inorganic layers may be formed as a total of 10 layers or less, e.g., 2 layers to 7 layers. In an implementation, the organic and inorganic layers may be formed as a total of 7 layers in the following order: inorganic layer/organic layer/inorganic layer/organic layer/inorganic layer/organic layer/inorganic layer.

In the barrier stack, the organic layers and the inorganic layers may be alternately deposited. This is based on consideration of benefits of the organic layers due to the aforementioned properties of the composition. Accordingly, the organic layer and the inorganic layer can supplement or reinforce each other in terms of encapsulation of the member for apparatuses.

Next, an organic light emitting diode display according to another embodiment will be described with reference to FIG. 2. FIG. 2 is a sectional view of an organic light emitting diode display according to another embodiment.

Referring to FIG. 2, an organic light emitting diode display 200 according to the embodiment may include a substrate 10, an organic light emitting diode 20 on the substrate 10, and a barrier stack 30 on the organic light emitting diode 20 and including an inorganic layer 31 and an organic layer 32. In an implementation, the inorganic layer 31 may encapsulate an inner space 40 receiving or accommodating the organic light emitting diode 20 therein. In an implementation, the organic layer 32 may be formed of the composition for encapsulation of organic light emitting diodes according to the embodiments. The organic light emitting display according to this embodiment may be substantially the same as the organic light emitting display according to the above embodiment, except that the inorganic layer does may not adjoin or directly contact the organic light emitting diode.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Preparative Example 1

### Preparation of Compound of Formula 3-2

In a 1,000 mL flask provided with a cooling tube and a stirrer, 300 mL of ethyl acetate, 21 g of 3,3-diphenyl-1,1,5,5-tetramethyltrisiloxane, and 43 g of allyl alcohol (Daejung Chemicals & Materials Co., Ltd.) were sequentially placed, followed by nitrogen purging for 30 minutes. Then, 72 ppm of Pt on carbon black powder (Aldrich) was added to the mixture, which in turn was heated to 80° C. and stirred for 4 hours. The remaining solvent was removed through distillation. With 71.5 g of the obtained compound placed in 300 mL of dichloromethane, 39 g of triethylamine was added thereto, followed by slowly adding 30.2 g of methacryloyl chloride thereto while stirring the mixture at 0° C. The remaining solvent was removed through distillation, thereby preparing a compound of Formula 3-2 having an HPLC purity of 96%. (¹H NMR: δ7.52, m, 6H; δ7.42, m, 4H; δ6.25, d, 2H; δ6.02, dd, 2H; δ5.82, t, 1H; δ5.59, d, 2H; δ3.86, m, 4H; δ1.52, m, 4H; δ0.58, m, 4H; δ0.04, m, 12H)

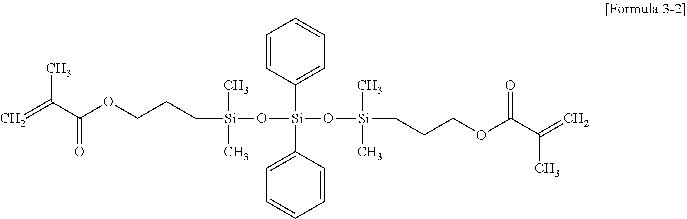 [SMILES: C=C(C)C(=O)OCCC[Si](C)(C)O[Si](O[Si](C)(C)CCCOC(=O)C(=C)C)(c1ccccc1)c1ccccc1]

Details of components used in Examples and Comparative Examples were as follows.

(A) First Photocurable Monomer

(Al) DMS-R₀₅ (methacryloxypropyl terminated polydimethylsiloxanes, Gelest, dimethacrylate, Mw: 420)

(A₂) DMS-R₁₁ (methacryloxypropyl terminated polydimethylsiloxanes, Gelest, dimethacrylate, Mw: 1,200)

(A3) M-262 (tricyclodecane dimethanol diacrylate, Miwon Specialty, Mw: 304.38)

(A5) M-370 (tris(2-hydroxyethyl)isocyanurate triacrylate, Miwon Specialty, Mw: 261.23)

(A6) M-410 (ditrimethylolpropane tetraacrylate, Miwon Specialty, Mw: 466)

(A7) M-300 (trimethylolpropane triacrylate, Miwon Specialty, Mw: 296.32)

(A8) Compound of Preparative Example 1 (Mw: 584.92)

(B) Second Photocurable Monomer

(B1) 2-phenylphenoxyethyl acrylate (M1142, Miwon, Mw: 268.31)

(B2) Lauryl acrylate (Mw: 240.38)

(B3) Isostearyl acrylate (Mw: 324.5)

(C) Phosphorus Initiator (Irgacure TPO)

### Example 1

64 parts by weight of (A₂), 33 parts by weight of (B1), and 3 parts by weight of (C) were placed in a 125 mL brown polypropylene bottle, and mixed by a shaker at ambient temperature for 3 hours, thereby preparing an encapsulation composition.

### Examples 2 to 6 and Comparative Examples 1 to 3

Encapsulation compositions were prepared in the same manner as in Example 1 except that the contents of the components of Example 1 were changed as listed in Table 1 (unit: parts by weight). In Table 1, “-” means that the corresponding component was absent.

Each of the compositions prepared in Examples and Comparative Examples was evaluated as to the following properties as listed in Table 1. Results are shown in Table 1.

(1) CLD: CLD of each of the encapsulation compositions prepared in Examples and Comparative Examples was calculated according to Equation 1.

(2) Viscosity (unit: cP): Viscosity of each of the encapsulation compositions prepared in Examples and Comparative Examples was measured at 24.8° C. using a viscometer Spindle No. 40 (LV DV-II Pro, Brookfield Co., Ltd.).

(3) Photocuring rate (unit: %): Each of the encapsulation compositions was measured as to intensity of absorption peaks in the vicinity of 1,635 cm⁻¹ (C═C) and 1,720 cm⁻¹ (C═O) using an FT-IR spectrometer (NICOLET 4700, Thermo Co., Ltd.). Each encapsulation composition was applied to a glass substrate using a sprayer, followed by curing through UV irradiation at 100 mW/cm² for 20 seconds, thereby preparing a specimen having a size of 20 cm×20 cm×3μm (width×length×thickness). Then, the intensity of absorption peaks of the cured film was measured in the vicinity of 1,635 cm⁻¹ (C═C) and 1,720 cm⁻¹ (C═O) using an FT-IR spectrometer (NICOLET 4700, Thermo Co., Ltd.). Photocuring rate was calculated by Equation 2:

Photocuring rate (%)−|1−(A/B)|×100 [Formula 2]

In Equation 2, A is a ratio of the intensity of an absorption peak in the vicinity of 1,635 cm⁻¹ to the intensity of an absorption peak in the vicinity of 1,720 cm⁻¹, as measured for the cured film, and B is a ratio of the intensity of an absorption peak in the vicinity of 1,635 cm⁻¹ to the intensity of an absorption peak in the vicinity of 1,720 cm⁻¹, as measured for the encapsulation composition.

(4) Ink-jet property: Each of the encapsulation compositions prepared in

Examples and Comparative Examples was ink-jetted at a drop speed of 2.5 μm/sec and at an ink-jet head temperature of 25° C. to 35° C. Upon ink-jetting, formation of spherical droplets was rated as ◯, formation of droplets having a usable spherical shape was rated as Δ, and formation of non-spherical droplets was rated as X.

(5) Hardness of organic layer (unit: kPa)): Each of the compositions prepared in Examples and Comparative Examples was coated to a thickness of 8 μm on a glass substrate, followed by curing through UV irradiation at 100 mW/cm² for 20 seconds, thereby preparing a specimen having a size of 20 cm×20 cm×3μm (width×length×thickness). After curing, hardness of the prepared organic layer specimen was measured using a Nano Indenter (G200, Keysight Technologies Co., Ltd.).

(6) Number of deposition times causing generation of wrinkles upon deposition of an inorganic layer on an organic layer formed of the composition: Each of the compositions of Examples and Comparative Examples was coated to a thickness of 8 μm on a glass substrate and cured through UV irradiation at 100 mW/cm² for 20 seconds, thereby preparing a specimen. SiNX was deposited on the specimen by PECVD (PLUS200-SP, QUROS). After each deposition round, the first number of deposition times in which generation of wrinkles were observed through an optical microscope was recorded.

TABLE 1

| | | Example | | | | | | Comparative Example | | |
|---|---|---|---|---|---|---|---|---|---|---|
| | | 1 | 2 | 3 | 4 | 5 | 6 | 1 | 2 | 3 |
| A | A1 | 64 | — | — | 50 | — | — | — | — | 40 |
| | A2 | — | 65 | 55 | — | — | — | — | 48 | — |
| | A3 | — | — | — | — | 30 | — | — | — | — |
| | A4 | — | — | — | — | — | 37 | 20 | — | 10 |
| | A5 | — | — | 10 | — | — | — | — | — | — |
| | A6 | — | — | — | — | 10 | — | — | — | — |
| | A7 | — | — | — | 10 | — | — | — | — | — |
| | A8 | — | 17 | — | — | — | 20 | — | — | — |
| B | B1 | 33 | 15 | — | — | 10 | 20 | 20 | — | 15 |
| | B2 | — | — | — | — | — | 20 | 57 | 34 | 32 |
| | B3 | — | — | 32 | 37 | 47 | — | — | 15 | — |

| | | | | | | | | | |
|---|---|---|---|---|---|---|---|---|---|
| C | 3 | 3 | 3 | 3 | 3 | 3 | 3 | 3 | 3 |
| CLD | 55.31 | 59.41 | 55.35 | 69.89 | 53.90 | 55.62 | 21.07 | 16.02 | 42.14 |
| Viscosity | 14.7 | 20.3 | 21.2 | 17.2 | 34.4 | 16.8 | 14 | 15.2 | 17.9 |
| Photocuring | 91 | 92 | 94 | 91 | 92 | 93 | 94 | 95 | 89 |
| rate | | | | | | | | | |
| Ink-jet | ◯ | ◯ | ◯ | ◯ | Δ | Δ | X | ◯ | ◯ |
| properties | | | | | | | | | |
| Hardness | 231 | 272 | 253 | 254 | 297 | 221 | 16 | 201 | 152 |
| Number of | 4 | 4 | 3 | 4 | 4 | 3 | 1 | 2 | 2 |
| deposition times | | | | | | | | | |
| causing wrinkle | | | | | | | | | |
| generation | | | | | | | | | |

As shown in Table 1, it may be seen that the compositions for encapsulation of organic light emitting diodes according to the Examples exhibited good hardness, minimized generation of wrinkles upon repeated formation of inorganic layers to secure good reliability, and had suitable viscosity to form an organic layer having a uniform surface while securing good photocuring rate and ink-jet properties.

The embodiments may provide a composition for encapsulation of organic light emitting diodes that may form an organic layer having good hardness. The embodiments may provide a composition for encapsulation of organic light emitting diodes that may form an organic layer having good reliability by suppressing generation of wrinkles upon repeated formation of inorganic layers. The embodiments may provide a composition for encapsulation of organic light emitting diodes that has suitable viscosity to form an organic layer having a uniform surface while securing good curing rate and ink-jet properties.

Conversely, Comparative Examples 1 to 3 having a CLD of less than 50, as calculated by Equation 1, failed to provide the effects of the embodiments.

By way of summation and review, if the inorganic layers are repeatedly formed on the organic layers and the organic layers do not have high hardness, wrinkles could be generated in the organic layer, thereby causing deterioration in reliability of the organic light emitting device. In order to increase hardness of the organic layer, a photocuring rate of the composition for encapsulation of organic light emitting diodes may be increased. There may be a limit in increasing the hardness by increasing the photocuring rate.

One or more embodiments may provide a composition for encapsulation of organic light emitting diodes that can form an organic layer having good hardness.

One or more embodiments may provide a composition for encapsulation of organic light emitting diodes that can form an organic layer having good reliability by suppressing generation of wrinkles upon repeated formation of inorganic layers.

One or more embodiments may provide a composition for encapsulation of organic light emitting diodes that has suitable viscosity to form an organic layer having a uniform surface and exhibits good curing rate and ink-jet properties.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A composition for encapsulation of organic light emitting diodes, the composition comprising photocurable monomers and having a CLD of 50 or more, as calculated by Equation 1:
$$CLD = \sum \frac{{M}_{x} ( {N}_{x} - 1 )}{{M}_{total}} \qquad [ Equation 1 ]$$
wherein, in Equation 1,
Mₜₒₜₐₗ is a total sum of a number of moles of the photocurable monomers in the composition,
Mₓ is a number of moles of an x^{th} photocurable monomer in the composition,
Nₓ is a number of photocurable functional groups per mole of the x^{th} photocurable monomer in the composition, and
x is an integer of 1 or more.

2. The composition as claimed in claim 1, wherein the composition has a CLD of 50 to 90.

3. The composition as claimed in claim 1, wherein:
the composition includes:
a first photocurable monomer;
a second photocurable monomer; and
an initiator,
the first photocurable monomer has at least two photocurable functional groups, and
the second photocurable monomer has a single photocurable functional group.

4. The composition as claimed in claim 3, wherein:
the first photocurable monomer is present in an amount of 35 parts by weight to 90 parts by weight,
the second photocurable monomer is present in an amount of 5 parts by weight to 60 parts by weight, and
the initiator is present in an amount of 1 part by weight to 10 parts by weight, all based on 100 parts by weight of total of the first photocurable monomer, the second photocurable monomer, and the initiator.

5. The composition as claimed in claim 3, wherein:
the first photocurable monomer includes a bifunctional (meth)acrylate represented by Formula 1, trimethylolpropane tri(meth)acrylate, pentaerythritol tri(meth)acrylate, dipentaerythritol tri(meth)acrylate, tris(2-hydroxyethyl)isocyanurate tri(meth)acrylate, pentaerythritol tetra(meth)acrylate, dipentaerythritol tetra(meth)acrylate, ditrimethylolpropane tetra(meth)acrylate, dipentaerythritol penta(meth)acrylate, or dipentaerythritol hexa(meth)acrylate,
Z₁—A₁—A—A₂—Z₂ [Formula 1]
in Formula 1,
A is a substituted or unsubstituted C₆ to C₂₀ alkylene group or a substituted or unsubstituted C₃ to C₂₀ cycloalkylene group;
A₁ and A₂ are each independently a single bond or a substituted or unsubstituted C₁ to C₁₀ alkylene group, and
Z₁ and Z₂ are each independently a group represented by Formula 2, 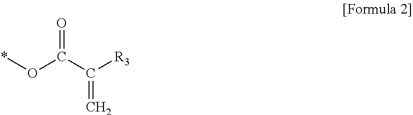
in Formula 2,
* is a linking site to A₁ or A₂, and
R₃ is hydrogen or a methyl group.

6. The composition as claimed in claim 3, wherein:
the first photocurable monomer includes a photocurable monomer represented by Formula 3: 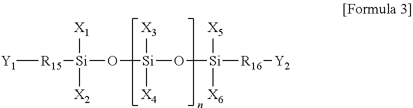
in Formula 3,
R₁₅ and R₁₆ are each independently a single bond, a substituted or unsubstituted C₁ to C₂₀ alkylene group, a substituted or unsubstituted C₁ to C₃₀ alkylene ether group, *—N(R′)—R″—*, in which * is a linkage site, R′ is a substituted or unsubstituted C₁ to Cao alkyl group, and R″ is a substituted or unsubstituted C₁ to C₂₀ alkylene group, a substituted or unsubstituted C₆ to C₃₀ arylene group, a substituted or unsubstituted C₇ to C₃₀ arylalkylene group, or *—O—G″—*, in which * is a linkage site and G″ is a substituted or unsubstituted C₁ to C₂₀ alkylene group;
X₁, X₂, X₃, X₄, X₅, and X₆ are each independently hydrogen, a substituted or unsubstituted C₁ to C₃₀ alkyl group, a substituted or unsubstituted C₁ to C₃₀ alkyl ether group, *—N(E′)(E″), in which * is a linkage site and E and E′ are each independently a hydrogen or a substituted or unsubstituted C₁ to C₃₀ alkyl group, a substituted or unsubstituted C₁ to C₃₀ alkyl sulfide group, a substituted or unsubstituted C₆ to C₃₀ aryl group, or a substituted or unsubstituted C₇ to C₃₀ arylalkyl group;
n ranges from 0 to 30 on average; and
Y₁ and Y₂ are each independently represented by Formula 4, 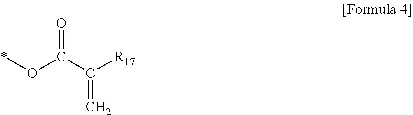
in Formula 4,
* is a linkage site to R₁₅ or R₁₆, and
R₁₇ is hydrogen or a methyl group.

7. The composition as claimed in claim 3, wherein the second photocurable monomer includes an aromatic photocurable monomer or a non-aromatic photocurable monomer.

8. The composition as claimed in claim 1, wherein the composition has a viscosity of 7 cP to 100 cP at 25±2° C.

9. An organic light emitting diode display apparatus comprising an organic layer prepared from the composition for encapsulation of organic light emitting diodes as claimed in claim 1.

10. The organic light emitting diode display apparatus as claimed in claim 9, wherein the composition has a CLD of 50 to 90.

11. The organic light emitting diode display apparatus as claimed in claim 9, wherein:
the composition includes:
a first photocurable monomer;
a second photocurable monomer; and
an initiator,
the first photocurable monomer has at least two photocurable functional groups, and
the second photocurable monomer has a single photocurable functional group.

12. The organic light emitting diode display apparatus as claimed in claim 11, wherein:
the first photocurable monomer is present in an amount of 35 parts by weight to 90 parts by weight,
the second photocurable monomer is present in an amount of 5 parts by weight to 60 parts by weight, and
the initiator is present in an amount of 1 part by weight to 10 parts by weight, all based on 100 parts by weight of total of the first photocurable monomer, the second photocurable monomer, and the initiator.

13. The organic light emitting diode display apparatus as claimed in claim 11, wherein:
the first photocurable monomer includes a bifunctional (meth)acrylate represented by Formula 1, trimethylolpropane tri(meth)acrylate, pentaerythritol tri(meth)acrylate, dipentaerythritol tri(meth)acrylate, tris(2-hydroxyethyl)isocyanurate tri(meth)acrylate, pentaerythritol tetra(meth)acrylate, dipentaerythritol tetra(meth)acrylate, ditrimethylolpropane tetra(meth)acrylate, dipentaerythritol penta(meth)acrylate, or dipentaerythritol hexa(meth)acrylate,
Z₁—A₁—A—A₂—Z₂ [Formula 1]
in Formula 1,
A is a substituted or unsubstituted C₆ to C₂₀ alkylene group or a substituted or unsubstituted C₃ to C₂₀ cycloalkylene group;
A₁ and A₂ are each independently a single bond or a substituted or unsubstituted C₁ to C₁₀ alkylene group, and
Z₁ and Z₂ are each independently a group represented by Formula 2, 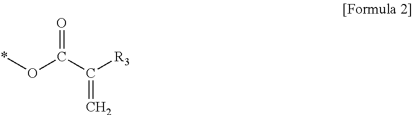
in Formula 2,
* is a linking site to A₁ or A₂, and
R₃ is hydrogen or a methyl group.

14. The organic light emitting diode display apparatus as claimed in claim 11, wherein:
the first photocurable monomer includes a photocurable monomer represented by Formula 3: 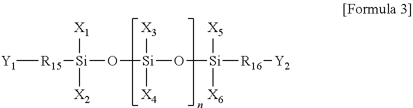
in Formula 3, R₁₅ and R₁₆ are each independently a single bond, a substituted or unsubstituted
C₁ to C₂₀ alkylene group, a substituted or unsubstituted C₁ to C₃₀ alkylene ether group, *—N(R′)—R″—*, in which * is a linkage site, R′ is a substituted or unsubstituted C₁ to Cao alkyl group, and R″ is a substituted or unsubstituted C₁ to C₂₀ alkylene group, a substituted or unsubstituted C₆ to C₃₀ arylene group, a substituted or unsubstituted C₇ to C₃₀ arylalkylene group, or *—O—G″—*, in which * is a linkage site and G″ is a substituted or unsubstituted C₁ to C₂₀ alkylene group; X₁, X₂, X₃, X₄, X₅, and X₆ are each independently hydrogen, a substituted or unsubstituted C₁ to C₃₀ alkyl group, a substituted or unsubstituted C₁ to C₃₀ alkyl ether group, *—N(E)(E″), in which * is a linkage site and E′ and E′ are each independently a hydrogen or a substituted or unsubstituted C₁ to C₃₀ alkyl group, a substituted or unsubstituted C₁ to C₃₀ alkyl sulfide group, a substituted or unsubstituted C₆ to C₃₀ aryl group, or a substituted or unsubstituted C₇ to C₃₀ arylalkyl group;
n ranges from 0 to 30 on average; and
Y₁ and Y₂ are each independently represented by Formula 4, 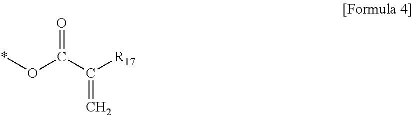
in Formula 4,
* is a linkage site to R₁₅ or R₁₆, and
R₁₇ is hydrogen or a methyl group.

15. The organic light emitting diode display apparatus as claimed in claim 11, wherein the second photocurable monomer includes an aromatic photocurable monomer or a non-aromatic photocurable monomer.

16. The organic light emitting diode display apparatus as claimed in claim 9, wherein the composition has a viscosity of 7 cP to 100 cP at 25±2° C.
